(19) United States
(12) Patent Application Publication
(10) Pub. No.: US 2025/0285785 A1
(43) Pub. Date: Sep. 11, 2025

(54) DRY FILM

(71) Applicant: Fujifilm Electronic Materials U.S.A., Inc., N. Kingstown, RI (US)

(72) Inventors: Sanjay Malik, Attleboro, MA (US); William A. Reinerth, Riverside, RI (US); Binod B. De, Attleboro, MA (US)

(21) Appl. No.: 19/215,817

(22) Filed: May 22, 2025

Related U.S. Application Data
(62) Division of application No. 17/793,197, filed on Jul. 15, 2022.
(60) Provisional application No. 62/961,740, filed on Jan. 16, 2020.

(51) Int. Cl. H01B 3/30; H01B 19/02; H01B 19/04

(52) U.S. Cl. CPC H01B 3/306; H01B 19/02; H01B 19/04

(57) ABSTRACT

This disclosure relates to a dry film structure that includes a carrier substrate; and a dielectric film supported by the carrier substrate. The dielectric film includes at least one dielectric polymer and low amounts of metals.

### CROSS-REFERENCE TO RELATED APPLICATION

The present application is a Division of and claims benefit under 35 U.S.C. § 120 from U.S. application Ser. No. 17/793,197, filed on Jul. 15, 2022, which is a U.S. National Phase application under 35 U.S.C. § 371 of International Patent Application No. PCT/US2020/066367, filed on Dec. 21, 2020, which claims priority to U.S. Provisional Application Ser. No. 62/961,740, filed on Jan. 16, 2020. The contents of each of these earlier applications are hereby incorporated by reference in their entirety.

### BACKGROUND OF THE DISCLOSURE

The amount of trace metals is an important aspect of next generation dielectric materials. For example, high power devices for advanced dielectric materials require extremely demanding electrical properties. Higher amounts of trace metal and ionic impurities in the dielectric film will cause current leakage between dense redistribution layers. These impurities will also negatively impact key electrical properties such as dielectric loss and dielectric constant. Levels of trace metal impurities that previously caused little or no issue in traditional dielectric materials, such as buffer coats, can no longer be tolerated. Therefore there is a need for dry film dielectric materials with extremely low trace metal impurities.

### SUMMARY OF THE DISCLOSURE

This disclosure addresses the above need by providing dielectric dry film structures (e.g., containing polyimide polymers) having very low levels of trace metals. Additionally, processes to achieve such low trace metal levels in dielectric dry film structures are disclosed.

In one aspect, this disclosure features a dry film structure that includes:
a) a carrier substrate; and
b) a dielectric film (or layer) supported by the carrier substrate, the dielectric film comprising at least one dielectric polymer (e.g., at least one fully imidized polyimide polymer), wherein the total amount of aluminum, chromium, cobalt, copper, iron, magnesium, manganese, nickel, silver, and zinc in the dielectric film is less than about 300 ppb of the dielectric film and the amount of each of these metals in the dielectric film is less than about 100 ppb of the dielectric film.

In another aspect, this disclosure features a dry film structure that includes:
a) a carrier substrate; and
b) a dielectric film (or layer) supported by the carrier substrate, the dielectric film comprising at least one dielectric polymer (e.g., at least one fully imidized polyimide polymer), wherein the total amount of aluminum, calcium, chromium, cobalt, copper, iron, magnesium, manganese, nickel, potassium, silver, sodium, and zinc in the dielectric film is less than about 500 ppb (e.g., less than about 300 ppb) of the dielectric film.

In another aspect, the dielectric film in the dry film structure of this disclosure can be a photosensitive dielectric film that includes:
a. at least one polyimide polymer;
b. at least one crosslinker; and
c. at least one catalyst, wherein the total amount of aluminum, chromium, cobalt, copper, iron, magnesium, manganese, nickel, silver, and zinc in the dielectric film is less than about 300 ppb of the dielectric film and the amount of each of these metals in the dielectric film is less than about 100 ppb of the dielectric film.

In yet another aspect, this disclosure features a process of preparing a dry film structure. The method includes:
(A) coating a carrier substrate (e.g., a substrate including at least one plastic film) with a dielectric film forming composition containing at least one dielectric polymer and at least one solvent to form a coated composition;
(B) drying the coated composition to form a dielectric film; and
(C) optionally applying a protective layer to the dielectric film. In some embodiments, the total amount of aluminum, chromium, cobalt, copper, iron, magnesium, manganese, nickel, silver, and zinc in the dielectric film is less than about 300 ppb of the dielectric film and the amount of each of those metals individually in the dielectric film is less than about 100 ppb of the dielectric film. In some embodiments, at least one step (e.g., two or three steps) of the above process (e.g., the entire process) is performed in a clean room.

### DETAILED DESCRIPTION OF THE DISCLOSURE

As used herein, the term “fully imidized” means the polyimide polymers of this disclosure are at least about 90% (e.g., at least about 95%, at least about 98%, at least about 99%, or about 100%) imidized. As used herein, the term “(meth)acrylates” include both acrylates and methacrylates. As used herein, the catalyst (e.g., an initiator) is a compound capable of inducing a polymerization or crosslinking reaction when exposed to heat and/or a source of radiation. As used herein, a crosslinker is a compound containing two or more alkenyl or alkynyl groups capable of a crosslinking or polymerization reaction in the presence of a catalyst. As used herein, the term “metal” includes both the ionic form of a metal (e.g., Al ion) or a metallic or element form of a metal (e.g., Al).

In some embodiments, this disclosure features a dry film structure that includes:
a) a carrier substrate; and
b) a dielectric film supported by the carrier substrate, the dielectric film containing at least one dielectric polymer, wherein the total amount of aluminum, chromium, cobalt, copper, iron, magnesium, manganese, nickel, silver, and zinc in the dielectric film is less than about 300 ppb of the dielectric film and the amount of each of these metals in the dielectric film is less than about 100 ppb of the dielectric film. In some embodiments, the dielectric film can include aluminum, calcium, chromium, cobalt, copper, iron, magnesium, manganese, nickel, potassium, silver, sodium, and zinc, and the total amount of these metals is less than about 500 ppb of the dielectric film.

In some embodiments, the dielectric polymer is selected from the group consisting of polyimides (e.g., fully imidized polyimides), polyimide precursor polymers, polybenzoxazoles, polybenzoxazole precursor polymers, (meth)acrylate polymers, epoxy polymers, polyurethanes, polyamides, polyesters, polyethers, novolac resins, benzocyclobutene resins, polystyrenes, and a mixture thereof.

In some embodiments, the dielectric film (e.g., an organic dielectric film) in the dry film structure of this disclosure can be prepared from a composition containing at least one fully imidized polyimide polymer and at least one solvent.

In some embodiments, the fully imidized polyimide polymer of the dielectric film is prepared by reaction of at least one diamine with at least one tetracarboxylic acid dianhydride.

Examples of suitable diamines include, but are not limited to, 1-(4-aminophenyl)-1,3,3-trimethylindan-5-amine (alternative names including 4,4′-[1,4-phenylene-bis(1-methylethylidene)] bisaniline), 1-(4-aminophenyl)-1,3,3-trimethyl-2H-inden-5-amine, 1-(4-aminophenyl)-1,3,3-trimethyl-indan-5-amine, [1-(4-aminophenyl)-1,3,3-trimethyl-indan-5-yl]amine, 1-(4-aminophenyl)-2,3-dihydro-1,3,3-trimethyl-1H-inden-5-amine, 5-amino-6-methyl-1-(3′-amino-4′-methylphenyl)-1,3,3-trimethylindan, 4-amino-6-methyl-1-(3′-amino-4′-methylphenyl)-1,3,3-trimethylindan, 5,7-diamino-1,1-dimethylindan, 4,7-diamino-1, 1-dimethylindan, 5,7-diamino-1, 1,4-trimethylindan, 5,7-diamino-1,1,6-trimethylindan, 5,7-diamino-1,1-dimethyl-4-ethylindan, p-phenylenediamine, m-phenylenediamine, o-phenylenediamine, 3-methyl-1,2-benzene-diamine, 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,2-diaminocyclohexane, 1,4-diaminocyclohexane, 1,3-cyclohexanebis(methylamine), 5-amino-1,3,3-trimethyl cyclohexanemethanamine, 2,5-diaminobenzotrifluoride, 3,5-diaminobenzotrifluoride, 1,3-diamino-2,4,5,6-tetrafluorobenzene, 4,4′-oxydianiline, 3,4′-oxydianiline, 3,3′-oxydianiline, 3,3′-diaminodiphenylsulfone, 4,4′-diaminodiphenylsulfones, 4,4′-isopropylidenedianiline, 4,4′-diaminodiphenylmethane, 2,2-bis(4-aminophenyl)propane, 4,4′ diaminodiphenyl propane, 4,4′-diaminodiphenyl sulfide, 4,4′-diaminodiphenylsulfone, 4-aminophenyl-3-aminobenzoate, 2,2′-dimethyl-4,4′-diaminobiphenyl, 3,3′-dimethyl-4,4′-diaminobiphenyl, 2,2′-bis (trifluoromethyl) benzidine, 3,3′-bis (trifluoromethyl) benzidine, 2,2-bis [4-(4-aminophenoxy phenyl)] hexafluoropropane, 2,2-bis (3-amino-4-methylphenyl)-hexafluoropropane, 2,2-bis(3-aminophenyl)-1,1,1,3,3,3-hexafluoropropane, 1,3-bis-(4-aminophenoxy)benzene, 1,3-bis-(3-aminophenoxy)benzene, 1,4-bis-(4-aminophenoxy)benzene, 1,4-bis-(3-aminophenoxy)benzene, 1-(4-aminophenoxy)-3-(3-aminophenoxy)benzene, 2,2′-bis-(4-phenoxyaniline)isopropylidene, bis(p-beta-amino-t-butylphenyl)ether, p-bis-2-(2-methyl-4-aminopentyl)benzene, p-bis(1,1-dimethyl-5-aminopentyl)benzene, 3,3′-dimethyl-4,4′-diaminobiphenyl, 4,4′-diaminobenzophenone, 3′-dichlorobenzidine, 2,2-bis [4-(4-aminophenoxy)phenyl] propane, 4,4′-[1,3-phenylenebis(1-methyl-ethylidene)] bisaniline, 4,4′-[1,4-phenylenebis(1-methyl-ethylidene)] bisaniline, 2,2-bis [4-(4-aminophenoxy)phenyl] sulfone, 2,2-bis [4-(3-aminophenoxy)benzene], 1,4-bis(4-aminophenoxy) benzene, 1,3-bis (4-aminophenoxy) benzene, (1,3′-bis (3-aminophenoxy) benzene, and 9H-fluorene-2,6-diamine. Any of these diamines can be used individually or in combination in any ratio as long as the resulting polyimide polymer satisfies the requirements of this disclosure.

Examples of suitable tetracarboxylic acid dianhydrides include, but are not limited to, pyrazine-2,3,5,6-tetracarboxylic dianhydride, thiophene-2,3,4,5-tetracarboxylic dianhydride, 2,3,5,6-pyridinetetracarboxylic acid dianhydride, norbornane-2,3,5,6-tetracarboxylic acid dianhydride, bicyclo [2.2.2]oct-7-ene-3,4,8,9-tetracarboxylic acid dianhydride, tetracyclo [4.4.1.0^{2,5}.0^{7,10}] undecane-1,2,3,4-tetracarboxylic acid dianhydride, 3,3′,4,4′-benzophenone tetracarboxylic dianhydride, 3,3′,4,4′-diphenylsulfone tetracarboxylic dianhydride, 3,3′,4,4′-diphenyl ether tetracarboxylic dianhydride, 2,3,3′,4′-diphenyl ether tetracarboxylic dianhydride, 2,2-[bis(3, 4-dicarboxyphenyl)] hexafluoropropane dianhydride, ethyleneglycol bis(anhydrotrimellitate), and 5-(2,5-dioxotetrahydro)-3-methyl-3-cyclohexene-1,2-dicarboxylic dianhydride. More preferred tetracarboxylic acid dianhydride monomers include 2,2-[bis(3, 4-dicarboxyphenyl)] hexafluoropropane dianhydride, 3,3′,4,4′-benzophenone tetracarboxylic dianhydride, 3,3′,4,4′-diphenylsulfone tetracarboxylic dianhydride, and 3,3′,4,4′-diphenyl ether tetracarboxylic dianhydride. Any of these tetracarboxylic acid dianhydrides can be used individually or in combination in any ratio as long as the resulting polyimide polymer satisfies the requirements of this disclosure.

In general, the fully imidized polyimide polymer thus formed is soluble in an organic solvent. In some embodiments, the fully imidized polyimide polymer can have a solubility in an organic solvent of at least about 50 mg/ml (e.g., at least about 100 mg/ml or at least about 200 mg/mL) at 25° C. Non-limiting examples of solvents includes tetrahydrofuran (THF), gamma-butyrolactone (GBL), tetrahydrofurfuryl alcohol (THFA), propylene glycol methyl ether acetate (PGMEA), propylene glycol methyl ether (PGME), methyl ethyl ketone (MEK), methyl isobutyl ketone (MIBK), or cyclopentanone (CP). These solvents can be used individually or in combination of 2, 3 or more.

In some embodiments, to synthesize the fully imidized polyimide (PI) polymer, a polyimide precursor polymer is prepared first. In some embodiments, the PI precursor polymer is a polyamic acid (PAA) polymer. In some embodiments, the PI precursor is a polyamic ester (PAE) polymer. In some embodiments, one or more diamine(s) are combined with one or more tetracarboxylic acid dianhydride(s) in at least one (e.g., two, three, or more) polymerization solvent to form a polyamic acid (PAA) polymer. In some embodiments, the PAA polymer formed is imidized, either chemically or thermally, to form a PI polymer. In some embodiments, the PAA polymer is end-capped by using an appropriate reagent during or after the polymer synthesis. In some embodiments, the PAA polymer formed is esterified to form a polyamic ester (PAE) polymer. In some embodiments, the PAE polymer is formed by reaction of a tetracarboxylic half ester with one or more diamines in at least one polymerization solvent. In some embodiments, the PAE polymer is end-capped by using an appropriate agent. In some embodiments, an end-capped PI polymer is synthesized from a PAA polymer or a PAE polymer containing an end-cap group. In some embodiments, such a PI polymer is end-capped after imidization.

In some embodiments, a chemical imidizing agent (e.g., a dehydrating agent) is added to a PAA polymer to catalyze the ring-closing dehydration process of the polyamic acid groups to form imide functionalities, thereby forming a PI polymer. Examples of suitable dehydrating agents include, but are not limited to, trifluoromethanesulfonic acid, methanesulfonic acid, p-toluenesulfonic acid, ethanesulfonic acid, butanesulfonic acid, perfluorobutanesulfonic acid, acetic anhydride, propionic anhydride, methacrylic anhydride and butyric anhydride. In addition, this dehydration process can be catalyzed by further addition of a basic catalyst. Examples of suitable basic catalysts include, but are not limited to, pyridine, triethylamine, tripropylamine, tributylamine, dicyclohexylmethylamine, 2,6-lutidine, 3,5-lutidine, picoline, 4-dimethylaminopyridine (DMAP) and the like.

In some embodiments, the fully imidized polyimide polymer is isolated without precipitation. In another preferred embodiment, the fully imidized polyimide polymer is purified without precipitation. Methods of isolating or purifying a polyimide polymer without precipitation has been described, e.g., in U.S. Pat. No. 9,617,386, the contents of which are incorporated herein by reference. Without wishing to be bound by theory, it is believed that using a polyimide polymer prepared without precipitation would significantly reduce the amount of trace metal in the polymer, thereby reducing the amount of trace metal in the dry film structure made from the polyimide polymer.

Methods to synthesize end-capped and non-endcapped PI precursor polymers are well known to those skilled in the art. Examples of such methods are disclosed in, e.g., U.S. Pat. Nos. 2,731,447, 3,435,002, 3,856,752, 4,026,876, 4,579,809, 4,629,777, 4,656,116, 4,960,860, 4,985,529, 5,006,611, 5,122,436, 5,252,534, 5,478,915, 5,773,559, 5,783,656, 5,969,055, and 9,617,386, the contents of which are hereby incorporated by reference. For example, U.S. Pat. No. 9,617,386 describes a method of preparing and isolating a polyimide polymer without precipitation. In a preferred embodiment, there is no need for purification of polymer by using an ion exchange resin or a chelating reagent. In some embodiments, methods for preparation of polyimide polymer specifically excludes use of ion exchange resin or chelating reagent.

In some embodiments, the weight average molecular weight (Mw) of the fully imidized polyimide polymer described herein is at least about 5,000 Daltons (e.g., at least about 10,000 Daltons, at least about 20,000 Daltons, at least about 25,000 Daltons, at least about 30,000 Daltons, at least about 35,000 Daltons, at least about 40,000 Daltons, or at least about 45,000 Daltons) and/or at most about 100,000 Daltons (e.g., at most about 90,000 Daltons, at most about 80,000 Daltons at most about 70,000 Daltons, at most about 65,000 Daltons, at most about 60,000 Daltons, at most about 55,000 Daltons, or at most about 50,000 Daltons). In one embodiment, the weight average molecular weight (Mw) of the fully imidized polyimide polymer is from about 20,000 Daltons to about 70,000 Daltons. In one embodiment, the weight average molecular weight (Mw) of the fully imidized polyimide polymer is from about 30,000 Daltons to about 80,000 Daltons. The weight average molecular weight can be obtained by gel permeation chromatography methods and calculated versus a polystyrene standard.

Methods to synthesize polybenzoxazole precursor polymers and polybenzoxazole polymers are also well known to those skilled in the art. Examples of such methods are disclosed in, e.g., U.S. Pat. Nos. 6,143,467, 6,127,086, 6,511,789, 7,056,641, 6,929,891, 7,101,652, 7,195,849, 7,129,011, and 9,519,216, the contents of which are hereby incorporated by reference.

Examples of suitable(meth)acrylate polymers include, but are not limited to, poly(N,N-dimethylamino ethyl acrylate), poly(benzyl methacrylate), poly(butyl methacrylate), poly(tert-butyl methacrylate), poly(butyl methacrylate-co-isobutyl methacrylate), poly(butyl methacrylate-co-methyl methacrylate), poly(cyclohexyl methacrylate), poly(2-ethylhexyl methacrylate), poly(ethyl methacrylate), poly(hexadecyl methacrylate), poly(hexyl methacrylate), poly(isobutyl methacrylate), poly(isopropyl methacrylate), poly(lauryl methacrylate-co-ethylene glycol dimethacrylate), poly(methyl methacrylate), poly(methyl methacrylate-co-ethyl acrylate), poly(methyl methacrylate-co-ethylene glycol dimethacrylate), poly(octadecyl methacrylate), poly(tetrahydrofurfuryl methacrylate), poly(tetrahydrofurfuryl methacrylate-co-ethyl methacrylate), poly(butyl acrylate), poly(ethyl acrylate), poly(2-ethylhexyl acrylate), and poly(methyl acrylate). These polymers are either commercially available or can be made by methods known in the art.

Examples of suitable epoxy polymers include, but are not limited to, bisphenol A epoxy polymers, bisphenol F epoxy polymers, novolac epoxy polymers, aliphatic epoxy polymers, and glycidylamine epoxy polymers. These polymers are either commercially available or can be made by methods known in the art.

In general, the present disclosure also features a dielectric film forming composition containing at least one dielectric polymer (e.g., at least one fully imidized polyimide polymer) and at least one organic solvent. Suitable organic solvents useful for forming the dielectric film forming composition should be able to dissolve or disperse all the components of the composition to form a homogeneous mixture. Selection of suitable solvents can also be based on the ability of the homogeneous solution thus form to be deposited by any of known methods and to produce a homogeneous film. The selection of suitable solvent can also depend on the ability of the solvent to boil off from the film in the operating temperature range (e.g., from 70° C. to 200° C.) such that the amount of residual solvent in the film is less than about 10% (e.g., less than about 9%, less than about 8%, less than about 7%, less than about 6%, less than about 5%, less than about 4%, less than about 3%, less than about 2%, or less than about 1%) of the total weight of the film. Non-limiting examples of solvents include tetrahydrofuran (THF), gamma-butyrolactone (GBL), tetrahydrofurfuryl alcohol (THFA), propylene glycol methyl ether acetate (PGMEA), propylene glycol methyl ether (PGME), methyl ethyl ketone (MEK), methyl isobutyl ketone (MIBK), and cyclopentanone (CP). These solvents can be used individually or in combination of 2, 3 or more.

In some embodiments, the dielectric film forming composition of this disclosure is photosensitive. In some embodiments, this composition further comprises at least one crosslinker and/or at least one catalyst.

In some embodiments, the at least one crosslinker contains at least two (meth)acrylate groups. In some embodiments, the crosslinker is selected from the group consisting of 1,6-hexanediol di(meth)acrylate, tetraethyleneglycol di(meth)acrylate, 1,12-dodecanediol di(meth)acrylate, 1,3-butylene glycol di(meth)acrylate, 1,4-butanediol di(meth)acrylate, cyclohexane dimethanol di(meth)acrylate, polyethylene glycol di(meth)acrylate, propoxylated (3) glycerol tri(meth)acrylate, divinylbenzene, ethoxylated bisphenol-A-di(meth)acrylate, diethylene glycol bis(allyl carbonate), trimethylolpropane tri(meth)acrylate, ditrimethylolpropane tetra(meth)acrylate, pentaerythritol tri(meth)acrylate, pentaerythritol tetra(meth)acrylate, dipentaerythritol penta-/hexa-(meth) acrylate, isocyanurate tri(meth)acrylate, bis(2-hydroxyethyl)-isocyanurate di(meth)acrylate, 1,3-butanediol tri(meth)acrylate, 1,4-butanediol tri(meth)acrylate, neopentyl glycol di(meth)acrylate, (meth)acrylate modified-urea-formaldehyde resins, (meth)acrylate modified melamine-formaldehyde resins and (meth)acrylate modified cellulose.

In some embodiments, the at least one crosslinker is at least one urethane acrylate oligomer. The term “urethane acrylate oligomer” refers to a class of urethane (meth) acrylate compounds that contain urethane linkages and have(meth)acrylate (e.g., acrylate or methacrylate) functional groups such as urethane multi(meth)acrylate, multiurethane(meth)acrylate, and multiurethane multi(meth)acrylate. Types of urethane (meth) acrylate oligomers have been described by, for example, Coady et al., U.S. U.S. Pat. No. 4,608,409 and by Chisholm et al., U.S. Pat. No. 6,844,950, the contents of which are hereby incorporated by reference. Specific examples of urethane acrylate oligomers useful in the present disclosure include, but are not limited to, CN9165US, CN9167US, CN972, CN9782, CN9783 and CN992. These and other urethane acrylate oligomers are commercially available from Arkema.

In some embodiments, the catalyst used in the composition for preparation of the dielectric film in the dry film structure of this disclosure is a photoinitiator, where the photoinitiator is a compound capable of generating free radicals when exposed to high energy radiation. Non-limiting examples of high energy radiation include electron beams, ultraviolet light, and X-ray. Without wishing to be bound by theory, it is believed that the photoinitiator induces a crosslinking or polymerization reaction involving the crosslinkers present in the composition that are capable of undergoing crosslinking or polymerization reaction.

Specific examples of photoinitiators include, but are not limited to, 1,2-Octanedione, 1-[4-(phenylthio)phenyl]-, 2-(O-benzoyloxime) (OXE-01 from BASF), 1-(O-Acetyloxime)-1-[9-ethyl-6-(2-methylbenzoyl)-9H-carbazol-3-yl]ethanone (OXE-02 from BASF), 1,8-octanedione, 1,8-bis [9-(2-ethylhexyl)-6-nitro-9H-carbazol-3-yl]-1,8-bis(O-acetyloxime), 2-hydroxy-2-methyl-1-phenylpropan-1-one, 1-hydroxycyclohexyl phenyl ketone (Irgacure 184 from BASF), a blend of 1-hydroxycyclohexylphenylketone and benzophenone (Irgacure 500 from BASF), 2,4,4-trimethylpentyl phosphine oxide (Irgacure 1800, 1850, and 1700 from BASF), 2,2-dimethoxyl-2-acetophenone (Irgacure 651 from BASF), bis(2,4,6-trimethyl benzoyl)phenyl phosphine oxide (Irgacure 819 from BASF), 2-methyl-1-[4-(methylthio)phenyl]-2-morphorinopropane-1-on (Irgacure 907 from BASF), (2,4,6-trimethylbenzoyl)diphenyl phosphine oxide (Lucerin TPO from BASF), ethoxy (2,4,6-trimethylbenzoyl)phenyl phosphine oxide (Lucerin TPO-L from BASF), a blend of phosphine oxide, hydroxy ketone and a benzophenone derivative (ESACURE KTO46 from Arkema), 2-hydroxy-2-methyl-1-phenylpropane-1-on (Darocur 1173 from Merck), 2-(benzoyloxyimino)-1-[4-(phenylthio)phenyl]-1-octanone (OXE-01, available from BASF), 1-(O-acetyloxime)-1-[9-ethyl-6-(2-methylbenzoyl)-9H-carbazol-3-yl]ethanone (OXE-02, available from BASF), NCI-831 (ADEKA Corp.), N-1919 (ADEKA Corp.), benzophenone, 2-chlorothioxanthone, 2-methylthioxanthone, 2-isopropylthioxanthone, benzodimethyl ketal, 1,1,1-trichloroacetophenone, diethoxyacetophenone, m-chloroacetophenone, propiophenone, anthraquinone, dibenzosuberone and the like.

Specific examples of nonionic-type photoinitiators include (5-toluylsulfonyloxyimino-5H-thiophen-2-ylidene)-2-methylphenyl-acetonitrile (Irgacure 121 from BASF), phenacyl p-methylbenzenesulfonate, benzoin p-toluenesulfonate, (p-toluene-sulfonyloxy) methylbenzoin, 3-(p-toluenesulfonyloxy)-2-hydroxy-2-phenyl-1-phenylpropyl ether, N-(p-dodecylbenzenesulfonyloxy)-1,8-naphthalimide, N-(phenyl-sulfonyloxy)-1,8-napthalimide, bis(cyclohexylsulfonyl) diazomethane, 1-p-toluenesulfonyl-1-cyclohexylcarbonyldiazomethane, 2-nitrobenzyl p-toluenesulfonate, 2,6-dinitrobenzyl p-toluenesulfonate, and 2,4-dinitrobenzyl p-trifluoromethylbenzenesulfonate and the like.

In some embodiments, an optional photosensitizer can be used in the dielectric film forming composition where the photosensitizer can absorb light in the wavelength range of 193 to 405 nm. Examples of photosensitizers include, but are not limited to, 9-methylanthracene, anthracenemethanol, acenaphthylene, thioxanthone, methyl-2-naphthyl ketone, 4-acetylbiphenyl, and 1,2-benzofluorene.

In embodiments where the crosslinking or polymerization reaction is initiated by heat, the catalyst used is a thermal initiator where the thermal initiator is a compound capable of generating free radicals when exposed to a temperature from about 70° C. to about 250° C. Without wishing to be bound by theory, it is believed that the thermal initiator induces a crosslinking or polymerization reaction involving crosslinkers present in the composition that are capable of undergoing crosslinking or polymerization reaction.

Specific examples of thermal initiators include, but are not limited to, benzoyl peroxide, cyclohexanone peroxide, lauroyl peroxide, tert-amyl peroxybenzoate, tert-butyl hydroperoxide, dicumyl peroxide, cumene hydroperoxide, succinic acid peroxide, di (n-propyl) peroxydicarbonate, 2,2-azobis(isobutyronitrile), 2,2-azobis(2,4-dimethylvaleronitrile), dimethyl-2,2-azobisisobutyrate, 4,4-azobis(4-cyanopentanoic acid), azobiscyclohexanecarbonitrile, 2,2-azobis(2-methylbutyronitrile) and the like.

In some embodiments, a combination of two or more catalysts can be used in the dielectric film forming composition. The combination of catalysts can be all thermal initiators, all photoinitiators, or a combination of thermal initiators and photoinitiators.

In some embodiments, the dielectric film forming composition of this disclosure further includes one or more adhesion promoter. Suitable adhesion promoters are described in “Silane Coupling Agent” Edwin P. Plueddemann, 1982 Plenum Press, New York. Classes of adhesion promoters include, but are not limited to, mercaptoalkoxysilanes, aminoalkoxysilanes, epoxyalkoxysilanes, glycidyloxyalkoxysilanes, mercaptosilanes, cyanatosilanes and imidazole silanes. In some embodiments, the adhesion promoter contains both an alkoxysilyl group and a functional group containing carbon-carbon multiple bond selected from substituted or unsubstituted alkenyl groups and substituted or unsubstituted alkynyl groups.

The dielectric film forming composition of this disclosure can also optionally contain one or more surfactant. Examples of suitable surfactants include, but are not limited to, the surfactants described in JP-A-62-36663, JP-A-61-226746, JP-A-61-226745, JP-A-62-170950, JP-A-63-34540, JP-A-7-230165, JP-A-8-62834, JP-A-9-54432 and JP-A-9-5988, the contents of which are incorporated herein by reference.

The dielectric film forming composition of the present disclosure can optionally contain one or more copper passivation reagent. Examples of copper passivation reagents include triazole compounds, imidazole compounds and tetrazole compounds. Triazole compounds can include triazole, benzotriazole, substituted triazole, and substituted benzotriazole. Examples of triazole compounds include, but are not limited to, 1,2,4-triazole, 1,2,3-triazole, or triazoles substituted with substituents such as C1-C8 alkyl (e.g., 5-methyltriazole), amino, thiol, mercapto, imino, carboxy and nitro groups. Specific examples include benzotriazole, tolyltriazole, 5-methyl-1,2,4-triazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, and the like. Examples of imidazole compounds include, but are not limited to, 2-alkyl-4-methyl imidazole, 2-phenyl-4-alkyl imidazole, 2-methyl-4 (5)-nitroimidazole, 5-methyl-4-nitroimidazole, 4-Imidazolemethanol hydrochloride, and 2-mercapto-1-methylimidazole. Examples of tetrazole compounds include, but are not limited to, 1-H-tetrazole, 5-methyl-1H-tetrazole, 5-phenyl-1H-tetrazole, 5-amino-1H-tetrazole, 1-phenyl-5-mercapto-1H-tetrazole, 5,5′-bis-1 H-tetrazole, 1-methyl-5-ethyltetrazole, 1-methyl-5-mercaptotetrazole, 1-carboxymethyl-5-mercaptotetrazole, and the like. The amount of the optional copper passivation agent, if employed, is at least about 0.05 weight % (e.g., at least about 0.1 weight % or at least about 0.5 weight %) and/or at most about 2 weight % (e.g., at most about 1.5 weight % or at most about 1.0 weight %) of the entire weight of the dielectric film forming composition.

The dielectric film forming composition of this disclosure can optionally contain one or more dyes and/or one or more colorants.

Suitable dyes are generally organic materials and include, for example, coumarin dyes such as coumarin 460 (blue), coumarin 6 (green), nile red or the like; hydrocarbon and substituted hydrocarbon dyes; polycyclic aromatic hydrocarbon dyes; scintillation dyes such as oxazole or oxadiazole dyes; aryl-or heteroaryl-substituted poly (C2-8) olefin dyes; carbocyanine dyes; indanthrone dyes; phthalocyanine dyes; oxazine dyes; carbostyryl dyes; napthalenetetracarboxylic acid dyes; porphyrin dyes; bis(styryl)biphenyl dyes; acridine dyes; anthraquinone dyes; cyanine dyes; methine dyes; arylmethane dyes; azo dyes; indigoid dyes; thioindigoid dyes; diazonium dyes; nitro dyes; quinone imine dyes; aminoketone dyes; tetrazolium dyes; thiazole dyes; perylene dyes; perinone dyes; bis-benzoxazolylthiophene (BBOT); triarylmethane dyes; xanthene dyes; thioxanthene dyes; naphthalimide dyes; lactone dyes; fluorophores such as anti-stokes shift dyes which absorb in the near infrared wavelength and emit in the visible wavelength, or the like; luminescent dyes such as 7-amino-4-methylcoumarin, 3-(2′-benzothiazolyl)-7-diethylaminocoumarin, 2-(4-biphenylyl)-5-(4-t-butylphenyl)-1,3,4-oxadiazole, 2,5-bis-(4-biphenylyl)-oxazole, 2,2′-dimethyl-p-quaterphenyl, 2,2-dimethyl-p-terphenyl, 3,5,3″,5″-tetra-t-butyl-p-quinquephenyl, 2,5-diphenylfuran, 2,5-diphenyloxazole, 4,4′-diphenylstilbene, 4-dicyanomethylene-2-methyl-6-(p-dimethylaminostyryl)-4H-pyran, 1,1′-diethyl-2,2′-carbocyanine iodide, 3,3′-diethyl-4,4′,5,5′-dibenzothiatricarbocyanine iodide, 7-dimethylamino-1-methyl-4-methoxy-8-azaquinolone-2, 7-dimethylamino-4-methylquinolone-2,2-(4-(4-dimethylaminophenyl)-1,3-butadienyl)-3-ethylbenzothiazolium perchlorate, 3-diethylamino-7-diethyliminophenoxazonium perchlorate, 2-(1-naphthyl)-5-phenyloxazole, and 2,2′-p-phenylen-bis(5-phenyloxazole); rhodamine 700; rhodamine 800; pyrene; chrysene; rubrene; coronene; or the like, or combinations comprising at least one of the foregoing dyes. Dyes are generally used in amounts of about 0.01 to about 20 parts by weight, based on 100 parts by weight of the polymer portion of the composition.

In some embodiments, the dielectric film forming composition of the present disclosure specifically excludes one or more of the following solvents, in any combination, if more than one. Such solvents can be selected from the group consisting of linear ketones such as methyl ethyl ketone (MEK), esters such as ethyl acetate, ester alcohols such as ethyl lactate, ether alcohols such as tetrahydrofurfuryl alcohol, and glycol esters such as propylene glycol methyl ether acetate (PGMEA).

In some embodiments, the dielectric film forming composition of the present disclosure specifically excludes one or more of the following adhesion promoters, in any combination, if more than one. Such adhesion promoters can be selected from the group consisting of primary amine containing adhesion promoters (such as 3-aminopropyl triethoxysilane and m-aminophenyl triethoxysilane), secondary amine containing adhesion promoters (such as N-cyclohexylamino trimethoxysilane), tertiary amine containing adhesion promoters (such as diethylaminoethyl triethoxysilane), urea containing adhesion promoters (such as ureidopropyl trimethoxysilane), anhydride containing adhesion promoters (such as 3-(triethoxysilyl)propyl succinic anhydride), epoxy containing adhesion promoters (such as 2-(3,4-epoxycyclohexyl)ethyl triethoxysilane), isocyanato containing adhesion promoters (such as 3-isocyanatopropyltriethoxysilane), and sulfur containing adhesion promoters (such as 3-mercaptopropyl trimethoxysilane).

In some embodiments, the dielectric film forming composition of the present disclosure specifically excludes one or more of additive components, in any combination, if more than one. Such components can be selected from the group consisting of non-polyimide polymers, non-crosslinking non-polyimide polymers, surfactants, plasticizers, colorants, dyes, water, oxygen scavengers, quaternary ammonium hydroxides, amines, alkali metal and alkaline earth bases (such as NaOH, KOH, LiOH, magnesium hydroxide, and calcium hydroxide), fluoride containing monomeric compounds, oxidizing agents (e.g., peroxides, hydrogen peroxide, ferric nitrate, potassium iodate, potassium permanganate, nitric acid, ammonium chlorite, ammonium chlorate, ammonium iodate, ammonium perborate, ammonium perchlorate, ammonium periodate, ammonium persulfate, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, urea hydrogen peroxide, and peracetic acid), abrasives, silicates, corrosion inhibitors (e.g., non-azole corrosion inhibitors), guanidine, guanidine salts, inorganic acids (e.g., sulfonic acids, sulfuric acid, sulfurous acid, nitrous acid, nitric acid, phosphorous acid, and phosphoric acid), organic acids (e.g., hydroxycarboxylic acids and carboxylic and polycarboxylic acids), pyrrolidone, polyvinyl pyrrolidone, and metal salts (e.g., metal halides).

In some embodiments, this disclosure features a method of preparing a dry film structure. The method includes:
(A) coating a carrier substrate (e.g., a substrate including at least one plastic film) with the dielectric film forming composition of this disclosure to form a coated composition;
(B) drying the coated composition to form a dielectric film; and
(C) optionally applying a protective layer to the dielectric film. In some embodiments, the total amount of aluminum, chromium, cobalt, copper, iron, magnesium, manganese, nickel, silver, and zinc in the dielectric film of the dry film structure of this disclosure is less than about 300 ppb of the dielectric film. In some embodiments, the total amount of aluminum, calcium, chromium, cobalt, copper, iron, magnesium, manganese, nickel, potassium, silver, sodium, and zinc in the dielectric film is less than about 500 ppb of the dielectric film. In some embodiments, the amount of each of those metals listed above individually is less than about 100 ppb of the dielectric film. In some embodiments, at least one step of the above process (e.g., the entire process) is performed in a clean room.

In some embodiments, the method for preparing a dry film structure having a low level of metal includes:
a) providing or synthesizing an organic solution containing a dielectric polymer (e.g., a polyimide such as a fully imidized polyimide) in at least one polar, aprotic polymerization solvent;
b) adding at least one purification solvent to the organic solution to form a diluted organic solution, the at least one purification solvent is less polar than the at least one polymerization solvent and has a lower water solubility than the at least one polymerization solvent at 25° C.;
c) washing the diluted organic solution with water or an aqueous solution to obtain a washed polymer-containing organic solution;
d) removing a portion of the at least one purification solvent in the washed polymer-containing organic solution to obtain a solution containing a purified dielectric polymer;
e) optionally adding additional components to the solution to form a dielectric film forming composition;
f) in a clean room set-up, coating a carrier substrate with the dielectric film forming composition (e.g., a solution containing a purified polyimide);
g) drying the coated composition to form a dielectric film; and
h) optionally applying a protective layer to the dielectric film. In some embodiments, one of more (e.g., two of three) of steps f), g), and h) can be performed in a clean room. In some embodiments, the dry film structure obtained by the above process can include a dielectric film that has low levels (such as those described herein) of metals.

In some embodiments, the dielectric film forming composition of this disclosure can be filtered prior to coating the composition on a carrier substrate. In some embodiments, the filter can have a relatively small pore size, such as at most about 1 μm (e.g., at most about 0.8 μm, at most about 0.5 μm, or at most about 0.2 μm).

In some embodiments, the dry film structure of this disclosure is prepared in a class 10000 clean room, a class 1000 clean room, a class 100 clean room, or a class 10 clean room (according to US FED STD 209E, succeeded by ISO 14644-1).

In some embodiments, the carrier substrate is a single or multiple layer plastic film, which can include one or more polymers (e.g., polyethylene terephthalate). In some embodiments, the carrier substrate has excellent optical transparency and it is substantially transparent to actinic irradiation used to form a relief pattern in the polymer layer. The thickness of the carrier substrate is preferably in the range of at least about 10 μm (e.g., at least about 15 μm, at least about 20 μm, at least about 30 μm, at least about 40 μm, at least about 50 μm or at least about 60 μm) to at most about 150 μm (e.g., at most about 140 μm, at most about 120 μm, at most about 100 μm, at most about 90 μm, at most about 80 μm, or at most about 70 μm).

In some embodiments, the protective layer is a single or multiple layer film, which can include one or more polymers (e.g., polyethylene or polypropylene). Examples of carrier substrates and protective layers have been described in, e.g., U.S. Application Publication No. 2016/0313642, the contents of which are hereby incorporated by reference.

In some embodiments, the total amount of metals (e.g., aluminum, calcium, chromium, cobalt, copper, iron, magnesium, manganese, nickel, potassium, silver, sodium, and zinc) in the dielectric film of the dry film structure of this disclosure is less than about 1000 ppb (e.g., less than about 800 ppb, less than about 600 ppb, less than about 500 ppb, less than about 300 ppb, less than about 280 ppb, less than about 260 ppb, less than about 240 ppb, less than about 220 ppb, less than about 200 ppb, less than about 150 ppb, less than about 100 ppb, less than about 50 ppb, or about 0 ppb) of the dielectric film. In some embodiments, the amount of each of those metals listed above individually in the dielectric film is less than about 100 ppb (e.g., less than about 90 ppb, less than about 80 ppb, less than about 70 ppb, less than about 60 ppb, less than about 50 ppb, less than about 40 ppb, less than about 30 ppb, less than about 20 ppb, less than about 10 ppb, or about 0 ppb) of the dielectric film.

In some embodiments, the amount of aluminum in the dielectric film of the dry film structure of this disclosure is less than about 30 ppb (e.g., less than about 25 ppb, less than about 20 ppb, less than about 15 ppb, less than about 10 ppb, less than about of 5 ppb, or about 0 ppb) of the dielectric film.

In some embodiments, the amount of calcium in the dielectric film of the dry film structure of this disclosure is less than about 300 ppb (e.g., less than about 250 ppb, less than about 200 ppb, less than about 150 ppb, less than about 100 ppb, less than about 50 ppb, or about 0 ppb) of the dielectric film.

In some embodiments, the amount of chromium in the dielectric film of the dry film structure of this disclosure is less than about 60 ppb (e.g., less than about 55 ppb, less than about 50 ppb, less than about 45 ppb, less than about 40 ppb, less than about of 35 ppb, less than about of 30 ppb, less than about of 25 ppb, less than about of 20 ppb, less than about of 15 ppb, less than about of 10 ppb, or less than about of 5 ppb, or about 0 ppb) of the dielectric film.

In some embodiments, the amount of cobalt in the dielectric film of the dry film structure of this disclosure is less than about 30 ppb (e.g., less than about 25 ppb, less than about 20 ppb, less than about 15 ppb, less than about 10 ppb, less than about of 5 ppb, or about 0 ppb) of the dielectric film.

In some embodiments, the amount of copper in the dielectric film of the dry film structure of this disclosure is less than about 60 ppb (e.g., less than about 55 ppb, less than about 50 ppb, less than about 45 ppb, less than about 40 ppb, less than about of 35 ppb, less than about of 30 ppb, less than about of 25 ppb, less than about of 20 ppb, less than about of 15 ppb, less than about of 10 ppb, or less than about of 5 ppb, or about 0 ppb) of the dielectric film.

In some embodiments, the amount of iron in the dielectric film of the dry film structure of this disclosure is less than about 80 ppb (e.g., less than about 70 ppb, less than about 65 ppb, less than about 60 ppb, less than about 55 ppb, less than about of 50 ppb, less than about of 45 ppb, less than about of 40 ppb, less than about of 35 ppb, less than about of 30 ppb, less than about of 25 ppb, less than about of 20 ppb, less than about of 15 ppb, less than about of 10 ppb, or less than about of 5 ppb, or about 0 ppb) of the dielectric film.

In some embodiments, the amount of magnesium in the dielectric film of the dry film structure of this disclosure is less than about 60 ppb (e.g., less than about 55 ppb, less than about 50 ppb, less than about 45 ppb, less than about of 40 ppb, less than about of 35 ppb, less than about of 30 ppb, less than about of 25 ppb, less than about of 20 ppb, less than about of 15 ppb, less than about of 10 ppb, or less than about of 5 ppb, or about 0 ppb) of the dielectric film.

In some embodiments, the amount of manganese in the dielectric film of the dry film structure of this disclosure is less than about 60 ppb (e.g., less than about 55 ppb, less than about 50 ppb, less than about 45 ppb, less than about 40 ppb, less than about of 35 ppb, less than about of 30 ppb, less than about of 25 ppb, less than about of 20 ppb, less than about of 15 ppb, less than about of 10 ppb, or less than about of 5 ppb, or about 0 ppb) of the dielectric film.

In some embodiments, the amount of nickel in the dielectric film of the dry film structure of this disclosure is less than about 30 ppb (e.g., less than about 25 ppb, less than about 20 ppb, less than about 15 ppb, less than about 10 ppb, or less than about 5 ppb, or about 0 ppb) of the dielectric film.

In some embodiments, the amount of potassium in the dielectric film of the dry film structure of this disclosure is less than about 300 ppb (e.g., less than about 250 ppb, less than about 200 ppb, less than about 150 ppb, less than about 100 ppb, less than about 50 ppb, or about 0 ppb) of the dielectric film.

In some embodiments, the amount of silver in the dielectric film of the dry film structure of this disclosure is less than about 40 ppb (e.g., less than about 35 ppb, less than about 32.5 ppb, less than about 30 ppb, less than about 25 ppb, less than about of 20 ppb, less than about of 15 ppb, less than about of 10 ppb, or less than about of 5 ppb, or about 0 ppb) of the dielectric film.

In some embodiments, the amount of sodium in the dielectric film of the dry film structure of this disclosure is less than about 300 ppb (e.g., less than about 250 ppb, less than about 200 ppb, less than about 150 ppb, less than about 100 ppb, less than about 50 ppb, or about 0 ppb) of the dielectric film.

In some embodiments, the amount of zinc in the dielectric film of the dry film structure of this disclosure is less than about 300 ppb (e.g., less than about 250 ppb, less than about 200 ppb, less than about 150 ppb, less than about 100 ppb, less than about 50 ppb, or about 0 ppb) of the dielectric film.

In some embodiments, the amount of titanium in the dielectric film of the dry film structure of this disclosure is less than about 30 ppb (e.g., less than about 25 ppb, less than about 20 ppb, less than about 15 ppb, less than about 10 ppb, less than about 5 ppb, or about 0 ppb) of the dielectric film.

In some embodiments, this disclosure features a process for construction of an article (e.g., a build-up layer stack) by using the dry film structure described herein. In some embodiments, the process can include the following steps:
(a) providing a substrate (e.g., an electronic substrate optionally laminated with a dielectric layer),
(b) optionally removing the protective layer of a dry film structure of this disclosure, if present,
(c) laminating the photosensitive dielectric film in the dry film structure to the substrate to form a laminate,
(d) exposing the photosensitive dielectric film to actinic radiation through a mask,
(e) baking the exposed dielectric film,
(f) developing the exposed areas of the dielectric film by an aqueous developer to form open areas in the dielectric film,
(g) selectively depositing a copper layer in open areas of the polymeric layer, and
(h) removing the dielectric film.
   In the above process, any carrier substrate can be removed after the lamination step and before the developing step (e.g., before or after the exposing step).

The steps (a) to (h) describe above can be applied as many times as needed on one or both sides of the substrate.

In general, the processes described above can be used to form an article to be used in a semiconductor device. Examples of such articles include a semiconductor substrate, a flexible film for electronics, a wire isolation, a wire coating, a wire enamel, or an inked substrate. Examples of semiconductor devices that can be made from such articles include an integrated circuit, a light emitting diode, a solar cell, and a transistor.

The following examples are provided to illustrate the principles and practice of the present disclosure more clearly. It should be understood that the present disclosure is not limited to the examples described.

### EXAMPLES

### Synthesis Example 1 (P-1)

### Preparation of 6FDA/DAPI polyimide

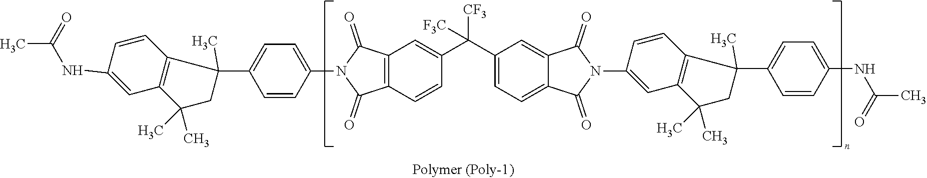

Solid 2,2′-bis(3,4-dicarboxyphenyl) hexafluoropropane dianhydride (6FDA) (3.34 Kg, 7.52 mole) was charged to a solution of 4,4′-[1,4-phenylene-bis(1-methylethylidene)] bisaniline (DAPI) (2.18 Kg, 8.19 mole) in NMP (22.06 Kg) at room temperature. Additional NMP (8.16 Kg) was used to rinse the dianhydride into solution. The reaction temperature was increased to 60° C. and the mixture was allowed to react for 3.5 hours. Next, acetic anhydride (1.257 Kg) and pyridine (495 g) were added, the reaction temperature was increased to 100° C., and the mixture was allowed to react for 12 hours.

The reaction mixture was cooled to room temperature and transferred to a larger vessel equipped with a mechanical stirrer. The reaction solution was diluted using ethyl acetate as a purification solvent and washed with water for one hour. Stirring was stopped and the mixture was allowed to stand undisturbed. Once phase separation had occurred, the aqueous phase was removed. The organic phase was diluted using a combination of cyclopentanone and toluene as purification solvents and washed three more times with water. The amounts of purification solvents (i.e., cyclopentanone and toluene) and water used in all of the washes are shown in Table 1.

TABLE 1

| | Wash 1 | Wash 2 | Wash 3 |
|---|---|---|---|
| Cyclopentanone (Kg) | 39.76 | 5.66 | 5.29 |
| Toluene (Kg) | 25.52 | — | — |
| Water (Kg) | 38.18 | 46.62 | 46.62 |

The washed organic phase was concentrated by vacuum distillation. cyclopentanone (7.1 Kg) was added as an isolation solvent and vacuum distillation was continued to form a polymer solution (P-1). The molecular weight of polymer Poly-1 was 53,500 Daltons and the solid % in the solution (P-1) was 31.85%. The molar ratio of dianhydride to diamine in this Example was 0.92.

### Dielectric Film Forming Composition of Example 1 (DFFC-1)

A dielectric film forming composition DFFC-1 was prepared by using 11548.23 g of polymer solution (P-1), 3381.82 g cyclopentanone, 220.69 g of a 0.5 wt % solution of PolyFox 6320 (available from OMNOVA Solutions) in cyclopentanone, 183.91 g of methacryloxypropyl trimethoxysilane, 110.34 g of NCI-831 (trade name, available from ADEKA corporation), 7.36 g para-benzoquinone, 1241.36 g of tetra-ethyleneglycol diacrylate, and 413.79 g pentaerythritol triacrylate. After being stirred mechanically for 24 hours, the solution was filtered by using a 0.2 micron PTFE filter to form a dielectric film forming composition DFFC-1.

### Dry Film Example DF-1

In a class 100 clean room environment, the filtered dielectric film forming composition of Example 1 (DFFC-1) was applied using reverse microbar coater from Fujifilm USA (Greenwood, SC) with line speed of 2 feet/minute (60 cm per minute) with 30 microns microbar clearance onto a polyethylene terephthalate (PET) film (TA 30, manufactured by Toray Plastics America, Inc.) having a width of 16.2 inches and thickness of 35 microns used as a carrier substrate and dried at 197° F. to obtain a photosensitive polymeric layer with a thickness of approximately 5.0 microns. On this polymeric layer, a biaxially oriented polypropylene film having width of 18 inches and thickness of 20 microns (BOPP, manufactured by Mirwec Film Inc., Bloomington, IN, trade name BOPLON) was laid over by a roll compression to act as a protective layer. The carrier substrate, polymeric layer, and protective layer formed dry film DF-1.

### Trace Metal Measurement for Dry Film (Dielectric Film) Example DF-1

About 2 g of the dielectric film in the dry film of example DF-1 was removed and was dissolved in 18 g of microelectronic grade gamma-butyrolactone. After a uniform solution was achieved, trace metals of solution was measured. Graphite furnace atomic absorption was used to measure the amount of aluminum, chromium, cobalt, copper, iron, magnesium, manganese, and silver. The amount of each metal is shown in Table 2.

TABLE 2
Amount of trace metals in the dielectric
film of the dry film of example DF-1

Amount (ppb)

| | | 100% |
|---|---|---|
| | Solution | dielectric |
| Metal | (10%) | film |
| Aluminum | 0 | 0 |
| Chromium | 0 | 0 |
| Cobalt | 0 | 0 |
| Copper | 0 | 0 |
| Iron | 3.6 | 36 |
| Magnesium | 2.61 | 26 |
| Manganese | 0.23 | 2 |
| Nickel | 0 | 0 |
| Silver | 1.80 | 18 |

In this example, the total amount of aluminum, chromium, cobalt, copper, iron, magnesium, manganese, nickel and silver was 82 ppb and the amount of each of those metals individually was at most 36 ppb.

### Dielectric Film Forming Composition of Example 2 (DFFC-2)

A dielectric film forming composition DFFC-2 was prepared by using 2197.80 g of polymer solution (P-1), 1108.79 g cyclopentanone, 42.0 g of a 0.5 wt % solution of PolyFox 6320 (available from OMNOVA Solutions) in cyclopentanone, 35.00 g of methacryloxypropyl trimethoxysilane, 35.00 g of 1-(O-acetyloxime)-1-[9-ethyl-6-(2-methylbenzoyl)-9H-carbazol-3-yl]ethanone (OXE-02 from BASF), 1.40 g para-benzoquinone, 288.75 g of tetra-ethyleneglycol diacrylate, and 96.25 g pentaerythritol triacrylate. After being stirred mechanically for 24 hours, the solution was filtered by using a 0.2 micron PTFE filter to form a dielectric film forming composition DFFC-2.

### Dry Film Example DF-2

In a class 100 clean room environment, the filtered dielectric film forming composition of Example 2 (DFFC-2) was applied using slot die coater from Fujifilm USA (Greenwood, SC) with line speed of 2 feet/minutes (60 cm per minutes) with 100 microns coating clearance onto a polyethylene terephthalate (PET) film (Hostaphan 3915, manufactured by Mitsubishi Polyester Film, Inc.) having a width of 20.2 inches and thickness of 35 microns used as a carrier substrate and dried at 197° F. to obtain a photosensitive polymeric layer with a thickness of approximately 6.5 microns. On this polymeric layer, a biaxially oriented polypropylene film having width of 18 inches and thickness of 20 microns (BOPP, manufactured by Mirwec Film Inc., Bloomington, IN, trade name BOPLON) was laid over by a roll compression to act as a protective layer. The carrier substrate, polymeric layer, and protective layer formed dry film DF-2.

### Trace Metal Measurement for Dry Film (Dielectric Film) Example DF-2

The amounts of trace metals in the dielectric film of the dry film DF-2 were measured using the same procedure as described in Example DF-1 and the results are summarized in Table 3.

TABLE 3
Amount of trace metals in the dielectric
film of the dry film of example DF-2

Amount (ppb)

| | | 100% |
|---|---|---|
| | Solution | dielectric |
| Metal | (10%) | film |
| Aluminum | 0 | 0 |
| Chromium | 2.39 | 24 |
| Cobalt | 0 | 0 |
| Copper | 3.61 | 36 |
| Iron | 4.78 | 48 |
| Magnesium | 2.41 | 24 |
| Manganese | 2.38 | 24 |
| Nickel | 0 | 0 |
| Silver | 1.20 | 12 |

In this example, the total amount of aluminum, chromium, cobalt, copper, iron, magnesium, manganese, nickel and silver was 168 ppb and the amount of each of those metals individually was at most 48 ppb.

### Synthesis Example 2

### Preparation of 6FDA/DAPI Polyimide

### Polymer (Poly-2)

Polymer (Poly-2) was prepared using the same procedures described in Synthesis Example 1 except that the molar ratio of dianhydrides to diamines increased to 0.96. Polymer (Poly-2) had a molecular weight of 67,800 Daltons and was isolated as 30.91% solid in cyclopentanone (polymer solution (P-2)).

### Synthesis Example 3

### Preparation of 6FDA/DAPI Polyimide

### Polymer (Poly-3)

Polymer (Poly-3) was prepared using the same procedures described in Synthesis Example 1 except that the molar ratio of dianhydrides to diamines was further increased to 0.97. Polymer (Poly-3) had a molecular weight of 69,400 Daltons and was isolated as 30.60% solid in cyclopentanone (polymer solution (P-3)).

### Dielectric Film Forming Composition of Example 3 (DFFC-3)

A dielectric film forming composition DFFC-3 was prepared by using 894.47 g of polymer solution (P-2), 351.37 g of polymer solution (P-3), 80.00 g cyclopentanone, 23.04 g of a 0.5 wt % solution of PolyFox 6320 (available from OMNOVA Solutions) in cyclopentanone, 19.20 g of methacryloxypropyl trimethoxysilane, 19.20 g of 1-(O-acetyloxime)-1-[9-ethyl-6-(2-methylbenzoyl)-9H-carbazol-3-yl]ethanone (OXE-02 from BASF), 0.77 g para-benzoquinone, 158.40 g of tetra-ethyleneglycol diacrylate, and 52.80 g pentaerythritol triacrylate. After being stirred mechanically for 24 hours, the solution was filtered by using a 0.2 micron PTFE filter to form a dielectric film forming composition DFFC-3.

### Dry Film Example DF-3

In a class 100 clean room environment, the filtered dielectric film forming composition DFFC-3 was applied using slot die coater from Fujifilm USA (Greenwood, SC) with line speed of 2 feet/minutes (60 cm per minutes) with 100 microns microbar clearance onto a polyethylene terephthalate (PET) film (Hostaphan 3915, manufactured by Mitsubishi Polyester Film, Inc.) having a width of 20.2 inches and thickness of 35 microns used as a carrier substrate and dried at 197° F. to obtain a photosensitive polymeric layer with a thickness of approximately 40 microns. On this polymeric layer, a biaxially oriented polypropylene film having width of 18 inches and thickness of 20 microns (BOPP, manufactured by Mirwec Film Inc., Bloomington, IN, trade name BOPLON) was laid over by a roll compression to act as a protective layer. The carrier substrate, polymeric layer, and protective layer formed dry film DF-3.

### Trace Metal Measurement for Dry Film (Dielectric Film) Example DF-3

The amounts of trace metals in the dielectric film of the dry film DF-3 were measured using the same procedure as described in Example DF-1 and the results are summarized in Table 4.

TABLE 4
Amount of trace metals in the dielectric
film of the dry film of example DF-3

Amount (ppb)

| | | 100% |
|---|---|---|
| | Solution | dielectric |
| Metal | (10%) | film |
| Aluminum | 0 | 0 |
| Chromium | 3.62 | 36 |
| Cobalt | 0 | 0 |
| Copper | 2.39 | 24 |
| Iron | 2.41 | 24 |
| Magnesium | 3.64 | 36 |
| Manganese | 1.18 | 12 |
| Nickel | 0 | 0 |
| Silver | 1.23 | 12 |

In this example, the total amount of aluminum, chromium, cobalt, copper, iron, magnesium, manganese, nickel and silver in dielectric film was 144 ppb and the amount of each of those metals individually was at most 36 ppb.

1-31. (canceled)

32. A process for preparing a dry film structure, comprising:
coating a carrier substrate with a dielectric film forming composition comprising at least one dielectric polymer and at least one solvent to form a coated composition; and
drying the coated composition to form a dielectric film on the carrier substrate,
wherein the at least one dielectric polymer comprises a fully imidized polyimide polymer that was isolated or purified without precipitation, and
wherein at least one of the following applies:
1) the total amount of aluminum, chromium, cobalt, copper, iron, magnesium, manganese, nickel, silver, and zinc in the dielectric film is less than about 300 ppb of the dielectric film and the amount of each of these metals in the dielectric film is less than about 100 ppb of the dielectric film; and
2) the total amount of aluminum, calcium, chromium, cobalt, copper, iron, magnesium, manganese, nickel, potassium, silver, sodium, and zinc in the dielectric film is less than about 500 ppb of the dielectric film.

33. The process of claim 32, further comprising applying a protective layer to the dielectric film.

34. The process of claim 32, wherein the process of performed in a clean room.

35. The process of claim 32, wherein the fully imidized polyimide polymer is prepared by adding a chemical imidizing agent to a polyimide precursor polymer.

36. The process of claim 35, wherein the chemical imidizing agent comprises any of trifluoromethanesulfonic acid, methanesulfonic acid, p-toluenesulfonic acid, ethanesulfonic acid, butanesulfonic acid, perfluorobutanesulfonic acid, acetic anhydride, propionic anhydride, methacrylic anhydride and butyric anhydride.

37. The process of claim 36, wherein the polyimide precursor polymer comprises a polyamic acid or a polyamic ester.

38. The process of claim 32, wherein the dielectric film forming composition is prepared by steps comprising:
a) synthesizing a dielectric polymer in an organic solution containing at least one polar, aprotic polymerization solvent;
b) adding at least one purification solvent to the organic solution to form a diluted organic solution, wherein the at least one purification solvent is less polar than the at least one polymerization solvent and has a lower water solubility than the at least one polymerization solvent at 25° C.;
c) washing the diluted organic solution with water or an aqueous solution to obtain a washed polymer-containing organic solution; and
d) removing a portion of the at least one purification solvent in the washed polymer-containing organic solution to obtain a solution containing a purified dielectric polymer,
wherein the dielectric film forming composition comprises the solution containing the purified dielectric polymer.

39. The process of claim 38, wherein the steps for preparing the dielectric film forming composition further comprises adding other components of a dielectric film forming composition to the solution.

40. The process of claim 38, wherein the steps for preparing the dielectric film forming composition further comprises concentrating the washed polymer-containing organic solution by vacuum distillation.

41. The process of claim 38, wherein the fully imidized polyimide polymer is prepared by adding a chemical imidizing agent to a polyimide precursor polymer.

42. The process of claim 32, wherein the amount of aluminum in the dielectric film is less than about 30 ppb of the dielectric film.

43. The process of claim 32, wherein the amount of chromium in the dielectric film is less than about 60 ppb of the dielectric film.

44. The process of claim 32, wherein the amount of cobalt in the dielectric film is less than about 30 ppb of the dielectric film.

45. The process of claim 32, wherein the amount of copper in the dielectric film is less than about 60 ppb of the dielectric film.

46. The process of claim 32, wherein the amount of iron in the dielectric film is less than about 80 ppb of the dielectric film.

47. The process of claim 32, wherein the amount of magnesium in the dielectric film is less than about 60 ppb of the dielectric film.

48. The process of claim 32, wherein the amount of manganese in the dielectric film is less than about 30 ppb of the dielectric film.

49. The process of claim 32, wherein the amount of nickel in the dielectric film is less than about 60 ppb of the dielectric film.

50. The process of claim 32, wherein the amount of silver in the dielectric film is less than about 40 ppb of the dielectric film.

51. The process of claim 32, wherein the dielectric film is photosensitive.

52. The process of claim 32, wherein the dielectric film further comprises a cross-linker.

53. The process of claim 32, wherein the dielectric film further comprises a catalyst.

54. The process of claim 53, wherein the catalyst is a photoinitiator or a thermal initiator.

55. The process of claim 32, wherein the dielectric film further comprises an adhesion promoter.

56. The process of claim 32, wherein the fully imidized polyimide polymer is purified without using an ion exchange resin.

57. The process of claim 32, wherein the total amount of aluminum, calcium, chromium, cobalt, copper, iron, magnesium, manganese, nickel, potassium, silver, sodium, and zinc in the dielectric film is less than about 300 ppb of the dielectric film.

58. The dry film structure prepared by the process of claim 32.

59. The dry film structure prepared by the process of claim 35.

60. The dry film structure prepared by the process of claim 41.
